(19) United States
(12) Patent Application Publication
(10) Pub. No.: US 2026/0247963 A1
(43) Pub. Date: Aug. 20, 2026

(54) ELECTRONIC DEVICE

(71) Applicants: Innolux Corporation, Miaoli County (TW); nD-HI Technologies Lab, Inc., Taipei City (TW)

(72) Inventors: Shu-Hsien Wu, Miaoli County (TW); Chih-Chao Chuang, Miaoli County (TW); Ching-Yu Chu, Miaoli County (TW); Shu-Fen Ku, Miaoli County (TW); Ho-Ming Tong, Taipei City (TW)

(73) Assignees: Innolux Corporation, Miaoli County (TW); nD-HI Technologies Lab, Inc., Taipei City (TW)

(21) Appl. No.: 19/444,209

(22) Filed: Jan. 9, 2026

Related U.S. Application Data
(60) Provisional application No. 63/758,334, filed on Feb. 14, 2025.

(30) Foreign Application Priority Data
Oct. 9, 2025 (CN) 202511437612.1

(51) Int. Cl. H10W 40/20; H10W 40/22; H10W 40/25; H10W 40/28; H10W 74/10

(52) U.S. Cl. CPC H10W 40/242; H10W 40/226; H10W 40/258; H10W 40/28; H10W 74/111; H10W 74/141

(57) ABSTRACT

An electronic device including a composite circuit stack is provided. The composite circuit stack includes a core substrate, at least one first heat transfer element, a first redistribution layer, a driving module, and an encapsulation layer. The at least one first heat transfer element is embedded in the core substrate. The first redistribution layer is disposed on the core substrate. The driving module is disposed on the first redistribution layer. The encapsulation layer surrounds the driving module.

### CROSS-REFERENCE TO RELATED APPLICATION

This application claims the priority benefit of U.S. provisional application serial no. 63/758,334, filed on February 14, 2025, and China application serial no. 202511437612.1, filed on October 9, 2025. The entirety of each of the above-mentioned patent applications is hereby incorporated by reference herein and made a part of this specification.

### BACKGROUND

### Technical Field

The disclosure relates to an electronic device, and more particularly, to an electronic device capable of enhancing heat dissipation efficiency.

### Description of Related Art

Electronic devices or splicing electronic devices have been commonly used in different fields such as communication, display, vehicle, or aviation. With the vigorous development of electronic devices, electronic devices are developed in the tendency of being thinner and lighter. Therefore, higher reliability or quality requirements are set for electronic devices.

### SUMMARY

According to an embodiment of the disclosure, an electronic device includes a composite circuit stack. The composite circuit stack includes a core substrate, at least one first heat transfer element, a first redistribution layer, a driving module, and an encapsulation layer. The at least one first heat transfer element is embedded in the core substrate. The first redistribution layer is disposed on the core substrate. The driving module is disposed on the first redistribution layer. The encapsulation layer surrounds the driving module.

To make the aforementioned more comprehensible, several embodiments accompanied with drawings are described in detail as follows.

### BRIEF DESCRIPTION OF THE DRAWINGS

FIG. 1 to FIG. 3 are cross-sectional schematic diagrams of a manufacturing method of an electronic device according to the first embodiment of the disclosure.

FIG. 4 is an enlarged schematic diagram of a first heat transfer element in the electronic device of FIG. 1.

FIG. 5 is a cross-sectional schematic diagram of an electronic device according to the second embodiment of the disclosure.

FIG. 6 to FIG. 8 are cross-sectional schematic diagrams of a manufacturing method of an electronic device according to the third embodiment of the disclosure.

FIG. 9 is a cross-sectional schematic diagram of an electronic device according to the fourth embodiment of the disclosure.

FIG. 10 is a cross-sectional schematic diagram of an electronic device according to the fifth embodiment of the disclosure.

### DESCRIPTION OF THE EMBODIMENTS

The disclosure can be understood by referring to the following detailed description in combination with the accompanying drawings. It should be noted that in order to make it easy for the reader to understand and for the simplicity of the drawings, the multiple drawings in this disclosure only depict a part of the electronic device/display device, and the specific components in the drawings are not drawn according to actual scale. In addition, the number and size of each component in the drawings are only for exemplary purpose, and are not intended to limit the scope of the disclosure.

In the following description and claims, the words "comprising" and "including" are open-ended words, and thus should be interpreted as meaning "including but not limited to...".

It should be understood that when an element or film is referred to as being "on" or "connected" to another element or film, the element or film may be directly on the other element or film or directly connected to the other element or film, or there is an intervening element or film between the two (indirectly). Conversely, when an element or film is said to be "directly" on or "directly connected" to another element or film, there is no intervening element or film between the two.

Although the terms "first", "second", "third", and the like may be used to describe various constituent elements, the constituent elements are not limited by the terms. This term is only used to distinguish a single constituent element from other constituent elements in the specification. The same terms may not be used in the claims, but replaced by first, second, third, . . . in the order in which the elements are recited in the claims. Therefore, in the following description, the first constituent element may be the second constituent element in the claims.

The terms "about", "roughly", "substantially", and "approximately" used in the text are generally interpreted as being within 10% of a given value or range, or interpreted as being within 5%, 3%, 2%, 1%, or 0.5% of a given value or range. The quantity given here is an approximate quantity, that is, in the absence of a specific description of "about", "roughly", "substantially", "approximately", the meaning of "about", "roughly", "substantially", "approximately" is still implicitly applied.

In some embodiments of the disclosure, terms such as "connected", "interconnected", etc., about joining and connecting, unless specifically defined, can mean that two structures are in direct contact, or that two structures are not directly in contact, where there are other structures located between the two structures. The terms of joining and connecting may also include the case where both structures are movable or both structures are fixed. In addition, the term "coupling" include any direct and indirect electrical connection means.

In some embodiments of the disclosure, optical microscopy (OM), scanning electron microscope (SEM), film thickness profiler (α-step), ellipsometer, or other suitable methods may be adopted to measure the area, width, thickness or height of various elements, or the distance or spacing between elements. In detail, according to some embodiments, an SEM may be used to obtain an image of cross-sectional structure including an elements to be measured, and measure the area, width, thickness or height of various elements, or distance or spacing between elements.

In the disclosure, the composite circuit stack may be applied to an electronic device. The electronic device may include a display device (including a transparent display device), a light-emitting device, a backlight device, a virtual reality device, an augmented reality (AR) device, an antenna device, a sensing device, a splicing device, a semiconductor device, or any combination thereof, but not limited thereto. The semiconductor device may be a central processing unit (CPU), a graphics processing unit (GPU), a memory, a field programmable gate array (FPGA), a silicon photonic and other higher power ICs, SoCs, and chiplets-in-SiP (system-in-a-package), where its application may extend to high-performance computing (HPC) and data centers, 5G/6G, artificial intelligence, electric vehicles (EV), Internet of Things (IoT), and other new terminal applications arising from the advent of the metaverse. Electronic elements in an electronic device may include passive elements and active elements, such as capacitors, resistors, inductors, diodes, transistors, and the like. It should be noted that, the electronic device may be any arrangement or combination of the foregoing, but not limited thereto. Hereinafter, the disclosure will be described with an electronic device, but the disclosure is not limited thereto.

It should be noted that, in the following embodiments, features in several different embodiments may be replaced, recombined, and mixed to complete other embodiments without departing from the spirit of the disclosure. As long as the features of the various embodiments do not violate the spirit of the disclosure or conflict with each other, they may be mixed and matched freely.

Reference will now be made in detail to the exemplary embodiments of the disclosure, examples of which are illustrated in the accompanying drawings. Wherever possible, the same reference numerals are used in the drawings and description to refer to the same or like parts.

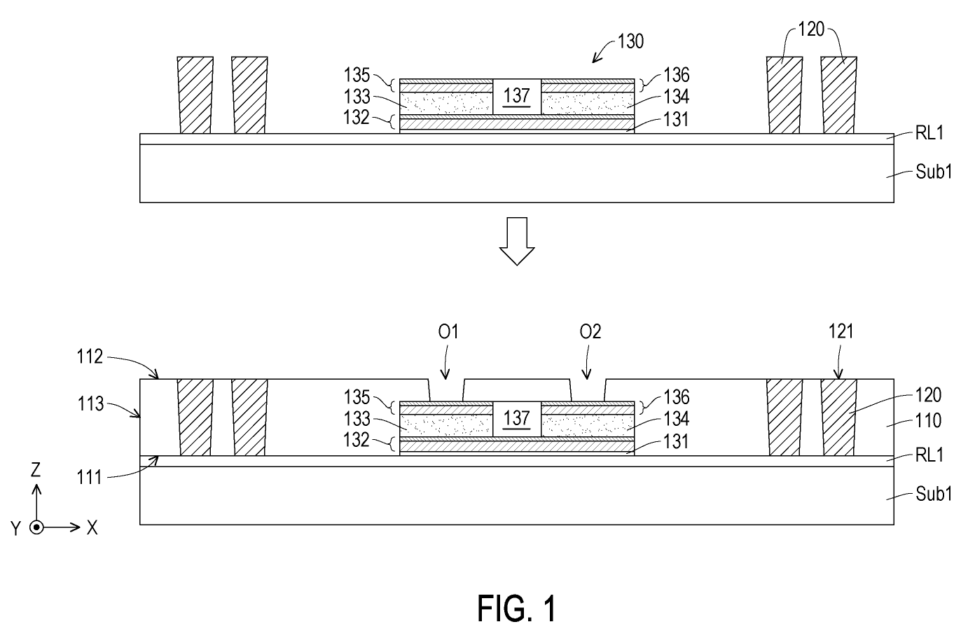

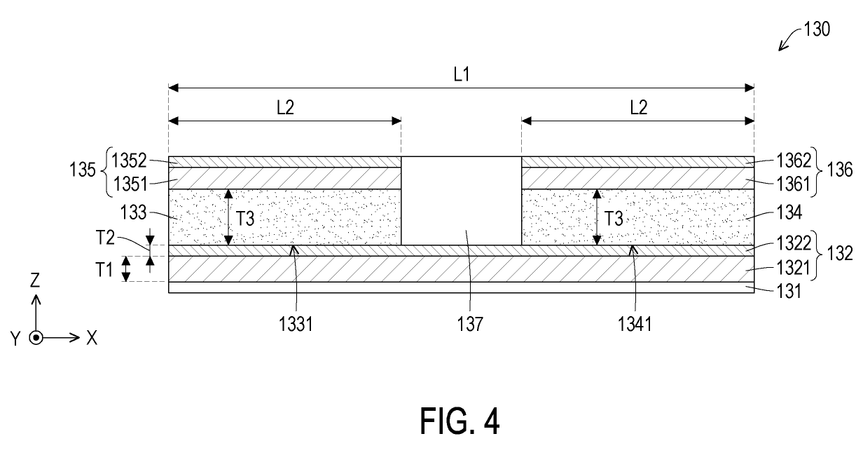

FIG. 1 to FIG. 3 are cross-sectional schematic diagrams of a manufacturing method of an electronic device according to the first embodiment of the disclosure. FIG. 4 is an enlarged schematic diagram of a first heat transfer element in the electronic device of FIG. 1.

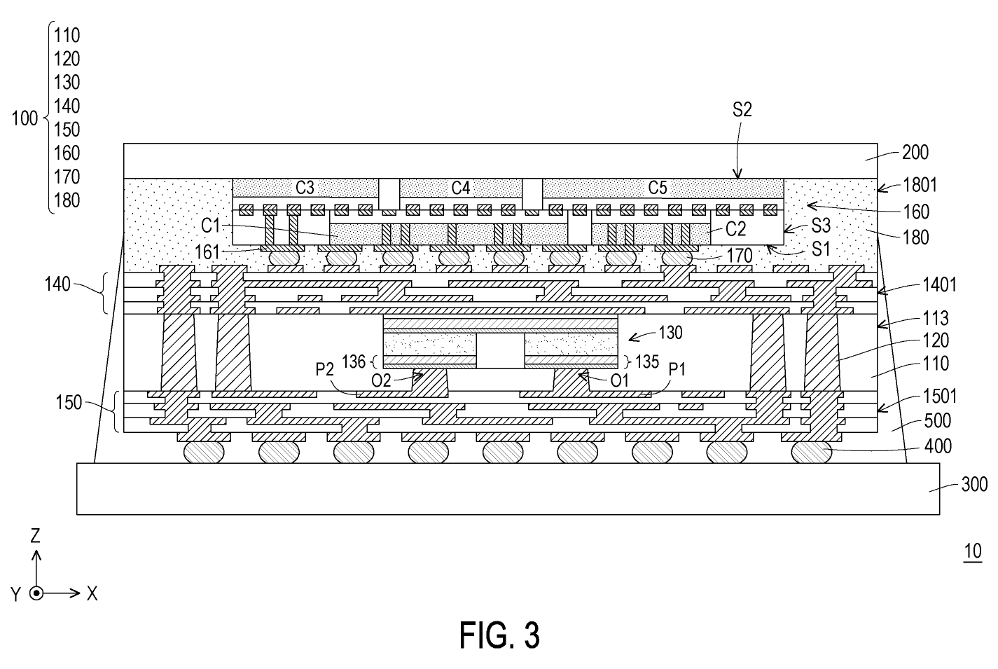

Referring to FIG. 3 first, an electronic device 10 of the embodiment includes a composite circuit stack 100, a heat sink 200, a circuit board 300, a connector 400, and an underfill 500.

Specifically, the composite circuit stack 100 is disposed on the circuit board 300 through the connector 400. The heat sink 200 is disposed on the composite circuit stack 100. The composite circuit stack 100 includes a core substrate 110, a copper pillar 120, at least one first heat transfer element 130, a first redistribution layer 140, a second redistribution layer 150, a driving module 160, a connector 170, and an encapsulation layer 180. The copper pillar 120 penetrates through the core substrate 110. The at least one first heat transfer element 130 is embedded in the core substrate 110. The first redistribution layer 140 is disposed on the core substrate 110. The second redistribution layer 150 and the first redistribution layer 140 are disposed on two opposite sides of the core substrate 110, respectively, and the second redistribution layer 150 may be electrically connected to the first redistribution layer 140 through the copper pillar 120. The driving module 160 is disposed on the first redistribution layer 140 through the connector 170. The encapsulation layer 180 surrounds the driving module 160.

In the embodiment, when the driving module 160 operates and generates heat, the heat generated by the driving module 160 may be transferred to the outside by the at least one first heat transfer element 130. Specifically, the heat generated by the driving module 160 may be first transferred to the first redistribution layer 140 through the connector 170. Next, the heat transferred to the first redistribution layer 140 may be further transferred to the second redistribution layer 150 through the first heat transfer element 130. Then, the heat transferred to the second redistribution layer 150 may be further transferred to the circuit board 300 through the connector 400, so that the heat generated by the driving module 160 may be transferred to the outside, thereby increasing the efficiency of heat dissipation.

Referring to FIG. 1 to FIG. 3, the manufacturing method of the electronic device 10 of the embodiment may include the following steps:

First, referring to FIG. 1, a substrate Sub1 is provided, and a release layer RL1 is formed on the substrate Sub1. In the embodiment, the material of the substrate Sub1 may include stainless steel, glass, other suitable substrate materials, or a combination thereof, but not limited thereto. In the embodiment, the material of the release layer RL1 may include thermal release materials that lose their adhesive properties when heated, UV release materials that lose their adhesive properties when exposed to ultraviolet light, other suitable release materials, or a combination thereof, but not limited thereto.

Next, referring to both FIG. 1 and FIG. 4, the copper pillar 120 and the first heat transfer element 130 are configured on the substrate Sub1, and the core substrate 110 is formed on the substrate Sub1. In detail, the copper pillar 120 and the first heat transfer element 130 are disposed on the release layer RL1, respectively.

The at least one first heat transfer element 130 may include a dielectric layer 131, a metal layer 132, an N-type semiconductor material 133, a P-type semiconductor material 134, a first electrode 135, a second electrode 136, and an insulation layer 137. Specifically, the dielectric layer 131 is disposed on the release layer RL1. The dielectric layer 131 has the effect of good thermal conduction and poor electrical conduction. In the embodiment, the thermal conductivity of the dielectric layer 131 may be 3 W/m·K to 5 W/m·K, and the material of the dielectric layer 131 may include ceramic filling, aluminum nitride composite resin, other dielectric materials with thermal conduction function, or a combination thereof, but not limited thereto.

The metal layer 132 is disposed on the dielectric layer 131. The metal layer 132 includes a first layer 1321 and a second layer 1322. The first layer 1321 is disposed between the second layer 1322 and the dielectric layer 131. In the embodiment, a length L1 of the metal layer 132 may be 0.5 to 2.0 millimeters (mm), a thickness T1 of the first layer 1321 may be 2 micrometers (μm), and a thickness T2 of the second layer 1322 may be 10 nanometers (nm), but not limited thereto. The length L1 may be the length of the metal layer 132 measured along direction X, the thickness T1 may be the thickness of the first layer 1321 measured along direction Z, and the thickness T2 may be the thickness of the second layer 1322 measured along direction Z. In the embodiment, the material of the first layer 1321 may be gold, and the material of the second layer 1322 may be chromium, but not limited thereto.

In the embodiment, direction X, direction Y, and direction Z are respectively different directions. Direction X is, for example, the extending direction of the core substrate 110 in FIG. 1, and direction Z is, for example, the normal direction of the core substrate 110 or the normal direction of the composite circuit stack 100. Direction X may be substantially perpendicular to direction Z, and direction X and direction Z may be substantially perpendicular to direction Y, respectively, but not limited thereto.

The N-type semiconductor material 133 and the P-type semiconductor material 134 are disposed on the second layer 1322 of the metal layer 132, respectively. The N-type semiconductor material 133 and the P-type semiconductor material 134 are physically separated from each other. The N-type semiconductor material 133 does not overlap the P-type semiconductor material 134 in direction Z. The N-type semiconductor material 133 and the P-type semiconductor material 134 may be electrically connected through the metal layer 132, thereby enabling the N-type semiconductor material 133 and the P-type semiconductor material 134 to be connected in series. A surface 1331 of the N-type semiconductor material 133 adjacent to the metal layer 132 and a surface 1341 of the P-type semiconductor material 134 adjacent to the metal layer 132 may be coplanar.

In the embodiment, a length L2 of the N-type semiconductor material 133 or the P-type semiconductor material 134 may be 0.2 to 0.9 mm, and a thickness T3 of the N-type semiconductor material 133 or the P-type semiconductor material 134 may be 0.5 to 1.0 mm, but not limited thereto. The length L2 may be the length of the N-type semiconductor material 133 or the P-type semiconductor material 134 measured along direction X, and the thickness T3 may be the thickness of the N-type semiconductor material 133 or the P-type semiconductor material 134 measured along direction Z.

In the embodiment, for example, the N-type semiconductor material 133 and the P-type semiconductor material 134 are formed by physical vapor deposition (PVD) combined with photolithography and etching methods, but not limited thereto. In addition, in the embodiment, the N-type semiconductor material 133 or the P-type semiconductor material 134 may include bismuth telluride (Bi₂Te₃), but not limited thereto.

The first electrode 135 and the second electrode 136 are correspondingly disposed on the N-type semiconductor material 133 and the P-type semiconductor material 134, respectively. The first electrode 135 and the second electrode 136 are physically separated from each other. The first electrode 135 and the metal layer 132 are located on two opposite sides of the N-type semiconductor material 133, respectively, and the second electrode 136 and the metal layer 132 are located on two opposite sides of the P-type semiconductor material 134, respectively. The first electrode 135 is electrically connected to the N-type semiconductor material 133, and the second electrode 136 is electrically connected to the P-type semiconductor material 134. The first electrode 135 includes a sublayer 1351 and a sublayer 1352, and the sublayer 1351 is disposed between the sublayer 1352 and the N-type semiconductor material 133. The second electrode 136 includes a sublayer 1361 and a sublayer 1362, and the sublayer 1361 is disposed between the sublayer 1362 and the P-type semiconductor material 134. In the embodiment, the material of the sublayer 1351 and the sublayer 1361 may be gold, and the material of the sublayer 1352 and the sublayer 1362 may be chromium, but not limited thereto.

The insulation layer 137 is disposed on the second layer 1322 of the metal layer 132. The insulation layer 137 is disposed between the N-type semiconductor material 133 and the P-type semiconductor material 134, and the insulation layer 137 may be used to separate the N-type semiconductor material 133 and the P-type semiconductor material 134. The insulation layer 137 is disposed between the first electrode 135 and the second electrode 136, and the insulation layer 137 may be used to separate the first electrode 135 and the second electrode 136.

In the embodiment, when current is applied to the first electrode 135 and the second electrode 136, the first heat transfer element 130 will have heat absorption capability on one side close to the metal layer 132, and will have heat dissipation capability on the other side close to the first electrode 135 and the second electrode 136, so that the first heat transfer element 130 may generate a heat transfer path to transfer the heat generated by the driving module 160 to the second redistribution layer 150 and the circuit board 300, thereby enabling the heat generated by the driving module 160 to be transferred to the outside and increasing the efficiency of heat dissipation.

Continuing to refer to FIG. 1, the core substrate 110 is disposed on the release layer RL1, and the core substrate 110 may contact a portion of the release layer RL1. The core substrate 110 may surround the copper pillar 120 and expose an upper surface 121 of the copper pillar 120. The core substrate 110 may surround the first heat transfer element 130. The core substrate 110 has a first surface 111, a second surface 112, a side surface 113, an opening O1, and an opening O2. The first surface 111 faces the substrate Sub1. The second surface 112 and the first surface 111 are opposite to each other, and the second surface 112 is coplanar with the upper surface 121 of the copper pillar 120. The side surface 113 connects the first surface 111 and the second surface 112. The opening O1 and the opening O2 may expose the first electrode 135 and the second electrode 136 of the first heat transfer element 130, respectively. In the embodiment, the material of the core substrate 110 may include epoxy molding compound (EMC), photosensitive polyimide (PSPI), ajinomoto build-up layer (ABF), other suitable substrate insulation materials, or a combination thereof, but not limited thereto.

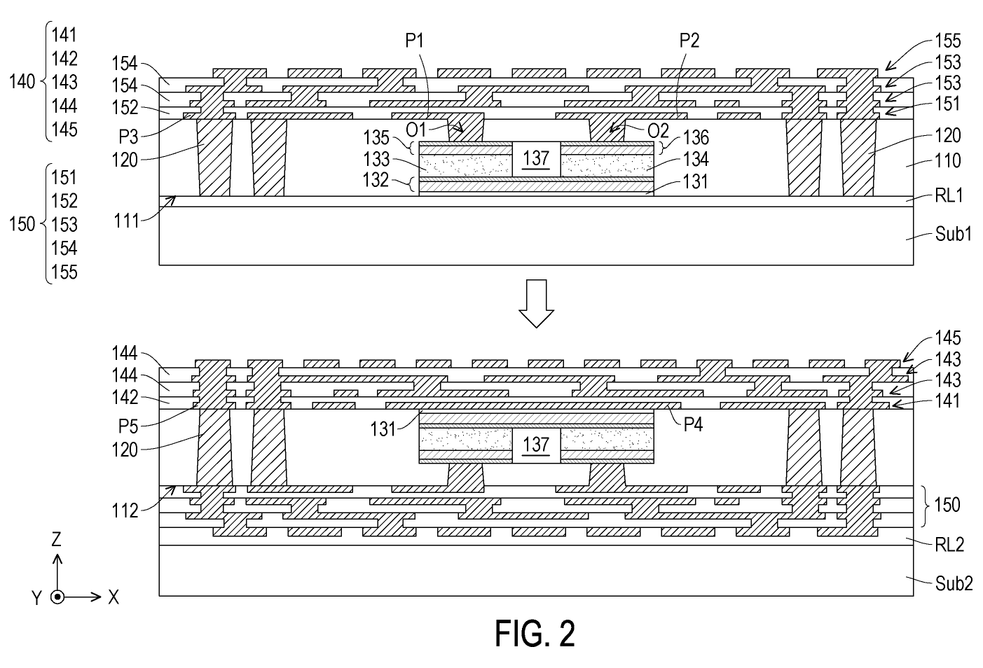

Next, referring to FIG. 2, the second redistribution layer 150 is formed on the core substrate 110. In detail, the second redistribution layer 150 is disposed on the second surface 112 of the core substrate 110. The second redistribution layer 150 includes, but is not limited to, a circuit layer 151, an insulation layer 152, a circuit layer 153, an insulation layer 154, and a circuit layer 155. The circuit layer 151 is disposed on the second surface 112 of the core substrate 110, the insulation layer 152 is disposed on the circuit layer 151, the circuit layer 153 is disposed on the insulation layer 152, the insulation layer 154 is disposed on the circuit layer 153, and the circuit layer 155 is disposed on the insulation layer 154. In the embodiment, the circuit layer 151 may include a pad P1, a pad P2, and a pad P3. The pad P1, the pad P2, and the pad P3 are disposed on the same layer and are separated from each other. The pad P1 may be electrically connected to the first electrode 135 through the opening O1, the pad P2 may be electrically connected to the second electrode 136 through the opening O2, and the pad P3 may contact and be electrically connected to the copper pillar 120.

Next, continuing to refer to FIG. 2, after removing the substrate Sub1 and the release layer RL1, the structure is flipped both vertically and horizontally and transferred onto the substrate Sub2 with the release layer RL2, and the first redistribution layer 140 is then formed on the core substrate 110. In detail, for example, the release layer RL1 loses its adhesive properties by heating or light irradiation to separate the substrate Sub1 from the core substrate 110. In the embodiment, the material of the substrate Sub2 may be the same as or similar to the material of the substrate Sub1, and the material of the release layer RL2 may be the same as or similar to the material of the release layer RL1, and description thereof is thus not repeated herein.

The first redistribution layer 140 is disposed on the first surface 111 of the core substrate 110. The first redistribution layer 140 may include, but is not limited to, a circuit layer 141, an insulation layer 142, a circuit layer 143, an insulation layer 144, and a circuit layer 145. Specifically, the circuit layer 141 is disposed on the first surface 111 of the core substrate 110, the insulation layer 142 is disposed on the circuit layer 141, the circuit layer 143 is disposed on the insulation layer 142, the insulation layer 144 is disposed on the circuit layer 143, and the circuit layer 145 is disposed on the insulation layer 144. In the embodiment, the circuit layer 141 may include a pad P4 and a pad P5. The pad P4 and the pad P5 are disposed on the same layer and are separated from each other. The pad P4 may contact the dielectric layer 131 to conduct heat generated by the driving module 160 to the first heat transfer element 130. The pad P5 may contact and be electrically connected to the copper pillar 120. In the embodiment, the first redistribution layer 140 may be electrically connected to the second redistribution layer 150 through the copper pillar 120.

Then, referring to FIG. 3, the connector 170 is formed, the driving module 160 is configured on the first redistribution layer 140, the encapsulation layer 180 is formed on the first redistribution layer 140, and the heat sink 200 is configured on the encapsulation layer 180.

In detail, the connector 170 is disposed between the driving module 160 and the first redistribution layer 140. In the embodiment, the connector 170 may be a solder ball, but not limited thereto.

The driving module 160 is bonded to the first redistribution layer 140 through the connector 170. The driving module 160 has a surface S1, a surface S2, and a side surface S3. The surface S1 and surface S2 are opposite to each other, the surface S1 faces the first redistribution layer 140, and the side surface S3 connects the surface S1 and the surface S2. The driving module 160 at least includes a pad 161 and multiple chips C1, C2, C3, C4, C5. The pad 161 is disposed on the surface S1, so that the driving module 160 may be electrically connected to the first redistribution layer 140 through the pad 161 and the connector 170. The chip C1 and the chip C2 are adjacent to the surface S1 and are separated from each other. The chip C3, the chip C4, and the chip C5 are adjacent to the surface S2 and are separated from each other. The multiple chips C1, C2, C3, C4, C5 generate heat during operation.

The encapsulation layer 180 may surround the driving module 160 and contact the side surface S3 of the driving module 160. The encapsulation layer 180 may also be disposed between the driving module 160 and the first redistribution layer 140.

The heat sink 200 is disposed on the encapsulation layer 180 and the surface S2 of the driving module 160. The heat sink 200 may contact the chip C3, the chip C4, and the chip C5 to conduct heat generated during operation of the driving module 160 to the outside.

In the embodiment, the first electrode 135 and second electrode 136 of the first heat transfer element 130 may also transfer the heat generated by the driving module 160 to the pad P1 and the pad P2 of the second redistribution layer 150 through the opening O1 and the opening O2 respectively, thereby increasing the efficiency of heat dissipation.

Then, continuing to refer to FIG. 3, after removing the substrate Sub2 and release layer RL2, the connector 400 is formed to configure the composite circuit stack 100 on the circuit board 300, and the underfill 500 is formed on the circuit board 300.

In detail, for example, the release layer RL2 loses its adhesive properties by heating or light irradiation to separate the substrate Sub2 from the second redistribution layer 150.

The connector 400 may be disposed between the second redistribution layer 150 of the composite circuit stack 100 and the circuit board 300. In the embodiment, the connector 400 may be a solder ball, but not limited thereto.

The composite circuit stack 100 may be bonded and electrically connected to the circuit board 300 through the connector 400.

The underfill 500 is disposed between the second redistribution layer 150 of the composite circuit stack 100 and the circuit board 300, and the underfill 500 may also cover a side 1801 of the encapsulation layer 180, a side 1401 of the first redistribution layer 140, the side surface 113 of the core substrate 110, and a side 1501 of the second redistribution layer 150. Thus far, the electronic device 10 of the embodiment has been substantially completed in manufacture.

Other examples are listed below for illustration. It should be noted here that the following embodiments use the element numbers and part of the contents of the previous embodiments, and the same numbers are used to represent the same or similar elements, and the description of the same technical contents is omitted. For the description of the omitted part, reference may be made to the foregoing embodiments, and no repetition is incorporated in the following embodiments.

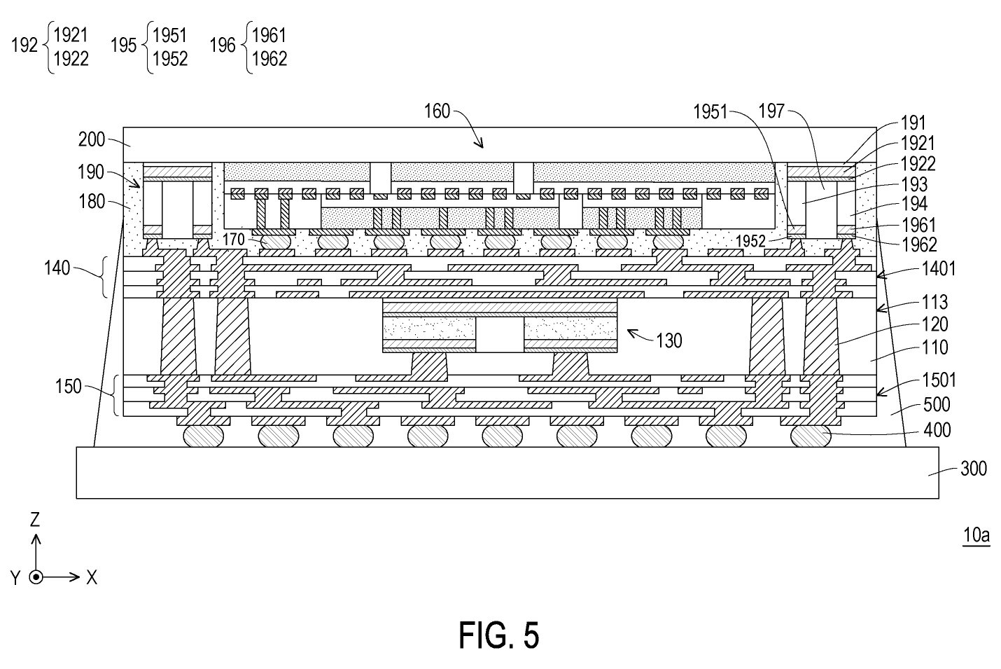

FIG. 5 is a cross-sectional schematic diagram of an electronic device according to the second embodiment of the disclosure. Referring to FIG. 5 and FIG. 3 at the same time, an electronic device 10a of the embodiment is similar to the electronic device 10 of FIG. 3, but the difference between the two lies in that, in the electronic device 10a of the embodiment, a composite circuit stack 100a further includes at least one second heat transfer element 190.

Specifically, referring to FIG. 5, the second heat transfer element 190 is embedded in the encapsulation layer 180 and adjacent to the driving module 160.

The second heat transfer element 190 may include a dielectric layer 191, a metal layer 192, an N-type semiconductor material 193, a P-type semiconductor material 194, a first electrode 195, a second electrode 196, and an insulation layer 197. The metal layer 192 may include a first layer 1921 and a second layer 1922. The first electrode 195 may include a sublayer 1951 and a sublayer 1952, and the second electrode 196 may include a sublayer 1961 and a sublayer 1962. In the embodiment, the configuration and material of the components in the second heat transfer element 190 may be substantially the same as or similar to the configuration and material of the components in the first heat transfer element 130, and description thereof is thus not repeated herein.

In the embodiment, when the driving module 160 operates and generates heat, the heat generated by the driving module 160 may be transferred to the outside by the first heat transfer element 130, and the heat generated by the driving module 160 may also be transferred to the outside by the second heat transfer element 190. Specifically, the heat generated by the driving module 160 may be directly transferred to the first redistribution layer 140 through the connector 170, and the heat generated by the driving module 160 may also be first transferred to the heat sink 200 and then transferred to the first redistribution layer 140 through the second heat transfer element 190. Next, the heat transferred to the first redistribution layer 140 may be further transferred to the second redistribution layer 150 through the copper pillar 120 and the first heat transfer element 130. Then, the heat transferred to the second redistribution layer 150 may be further transferred to the circuit board 300 through the connector 400, so that the heat generated by the driving module 160 may be transferred to the outside, thereby achieving the heat dissipation effect and increasing the heat dissipation efficiency.

More specifically, in the embodiment, when current is applied to the first electrode 195 and the second electrode 196 in the second heat transfer element 190, the second heat transfer element 190 will have heat absorption capability on one side close to the metal layer 192, and will have heat dissipation capability on the other side close to the first electrode 195 and the second electrode 196, so that the second heat transfer element 190 may generate a heat transfer effect in which the heat transferred to the heat sink 200 is transferred to the first redistribution layer 140.

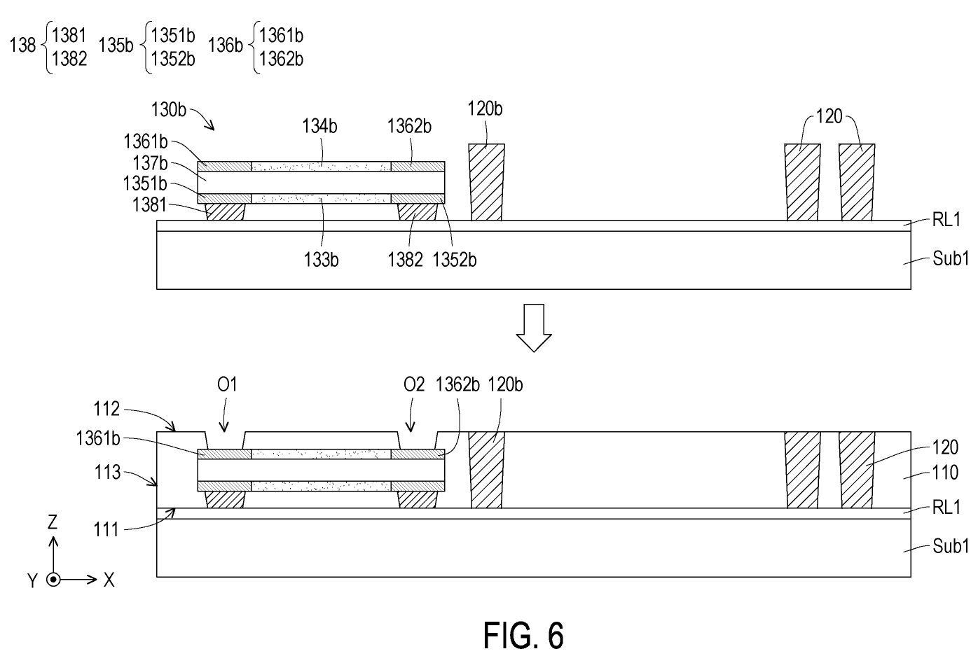

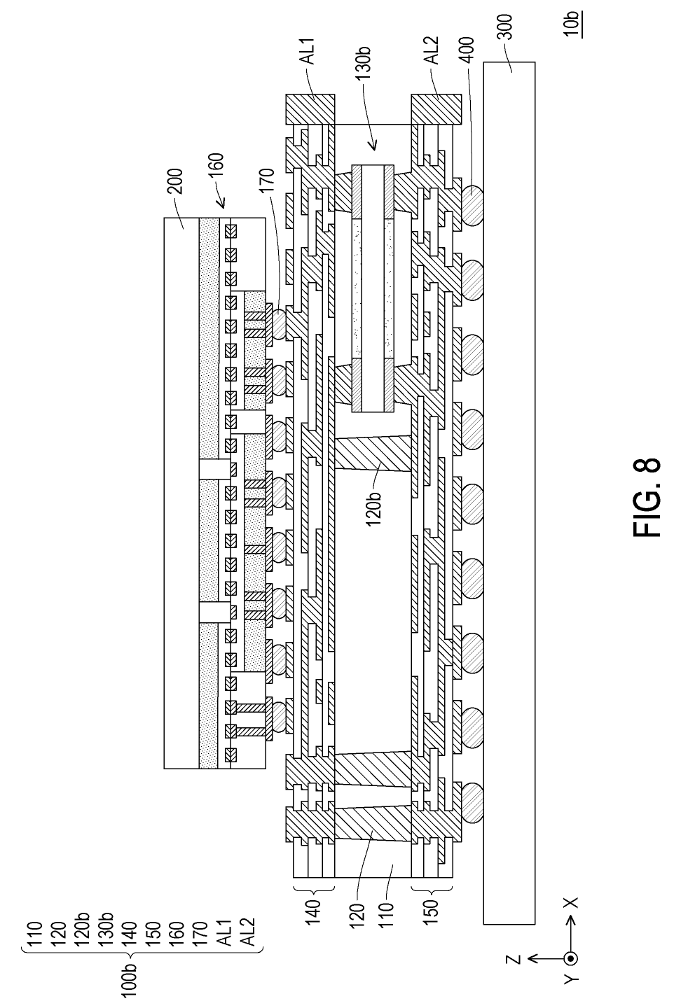

FIG. 6 to FIG. 8 are cross-sectional schematic diagrams of a manufacturing method of an electronic device according to the third embodiment of the disclosure. The same or similar components in the embodiments of FIG. 6 to FIG. 8 and the embodiments of FIG. 1 to FIG. 3 may be implemented using the same materials or methods, so the same and similar descriptions in the two embodiments is thus not repeated herein, and the explanation will mainly focus on the differences between the two embodiments. In addition, referring to both FIG. 8 and FIG. 3, an electronic device 10b of the embodiment is similar to the electronic device 10 of FIG. 3, but the difference between the two lies in that, in the electronic device 10b of the embodiment, a composite circuit stack 100b further includes an assist layer AL1 and an assist layer AL2, and the configuration of the components in a first heat transfer element 130b is different from the configuration of the components in the first heat transfer element 130 in FIG. 3.

The manufacturing method of the electronic device 10b of the embodiment may include the following steps:

First, referring to FIG. 6, a substrate Sub1 is provided, a release layer RL1 is formed on the substrate Sub1, a copper pillar 120, a copper pillar 120b, and a first heat transfer element 130b are provided on the substrate Sub1, and a core substrate 110 is formed on the substrate Sub1.

In detail, the material of the core substrate 110 may include epoxy molding compound, photosensitive polyimide, ajinomoto build-up layer, other suitable substrate insulation materials, or a combination thereof, but not limited thereto.

The first heat transfer element 130b may include an N-type semiconductor material 133b, a P-type semiconductor material 134b, a first electrode 135b, a second electrode 136b, an insulation layer 137b, and a metal layer 138. Specifically, the metal layer 138 is disposed on the release layer RL1, and the metal layer 138 includes a metal pad 1381 and a metal pad 1382 separated from each other.

The first electrode 135b is disposed on the metal layer 138. The first electrode 135bincludes a sub-electrode 1351b and a sub-electrode 1352b separated from each other. The sub-electrode 1351b is disposed corresponding to the metal pad 1381, and the sub-electrode 1352b is disposed corresponding to the metal pad 1382.

The N-type semiconductor material 133b is disposed on the metal layer 138. The N-type semiconductor material 133b is at the same layer as the first electrode 135b, and the N-type semiconductor material 133b is disposed between the sub-electrode 1351b and the sub-electrode 1352b. The N-type semiconductor material 133b may contact and be electrically connected to the sub-electrode 1351b and the sub-electrode 1352b.

The insulation layer 137b is disposed on the metal layer 138 and the N-type semiconductor material 133b.

The second electrode 136b is disposed on the insulation layer 137b. The second electrode 136b includes a sub-electrode 1361b and a sub-electrode 1362b separated from each other. The sub-electrode 1361b is disposed corresponding to the sub-electrode 1351b, and the sub-electrode 1362b is disposed corresponding to the sub-electrode 1352b. In the embodiment, the material of the first electrode 135b and the second electrode 136b may be gold, but not limited thereto.

The P-type semiconductor material 134b is disposed on the insulation layer 137b. The P-type semiconductor material 134b is at the same layer as the second electrode 136b, and the P-type semiconductor material 134b is disposed between the sub-electrode 1361b and the sub-electrode 1362b. The P-type semiconductor material 134b may contact and be electrically connected to the sub-electrode 1361b and the sub-electrode 1362b.

In the embodiment, the insulation layer 137b is disposed between the N-type semiconductor material 133b and the P-type semiconductor material 134b, and the insulation layer 137b may be used to separate the N-type semiconductor material 133b and the P-type semiconductor material 134b. The insulation layer 137b is disposed between the first electrode 135b and the second electrode 136b, and the insulation layer 137b may be used to separate the first electrode 135b and the second electrode 136b.

In the embodiment, the N-type semiconductor material 133b and the P-type semiconductor material 134b are stacked along the normal direction of the composite circuit stack 100b (i.e., direction Z), and the N-type semiconductor material 133b may overlap the P-type semiconductor material 134b in direction Z.

In another embodiment, the P-type semiconductor material 134b and the N-type semiconductor material 133b are stacked along the normal direction of the composite circuit stack 100b (i.e., direction Z).

The core substrate 110 has a first surface 111, a second surface 112, a side surface 113, an opening O1, and an opening O2. In the embodiment, the opening O1 and the opening O2 may expose the sub-electrode 1361b and the sub-electrode 1362b of the second electrode 136b, respectively.

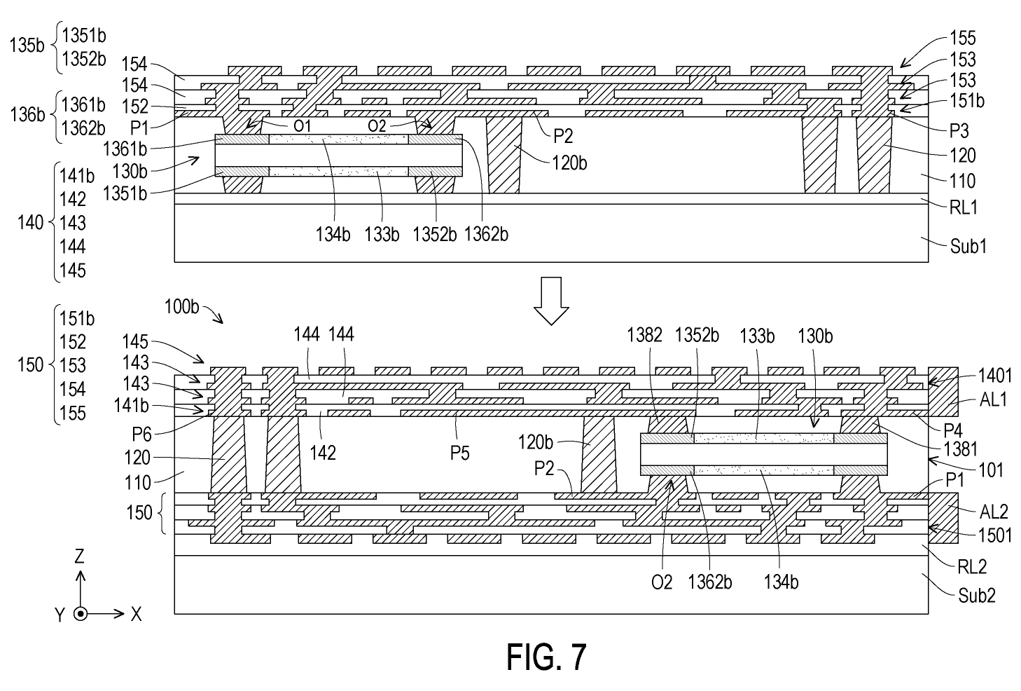

Then, referring to FIG. 7, a second redistribution layer 150 is formed on the second surface 112 of the core substrate 110. In the embodiment, a circuit layer 151b of the second redistribution layer 150 may include a pad P1, a pad P2, and a pad P3. The pad P1, the pad P2, and the pad P3 are disposed on the same layer and separated from each other. The pad P1 may be electrically connected to the sub-electrode 1361b of the second electrode 136b through the opening O1. The pad P2 may be electrically connected to the sub-electrode 1362b of the second electrode 136b through the opening O2, and the pad P2 may also contact and be electrically connected to the copper pillar 120b. The pad P3 may contact and be electrically connected to the copper pillar 120.

Next, continuing to refer to FIG. 7, after removing the substrate Sub1 and the release layer RL1, the structure is flipped both vertically and horizontally and transferred onto the substrate Sub2 with the release layer RL2, a first redistribution layer 140 is formed on the first surface 111 of the core substrate 110, and the assist layer AL1 and the assist layer AL2 are formed on a side 101 of the composite circuit stack 100b.

In the embodiment, a circuit layer 141b in the first redistribution layer 140 may include a pad P4, a pad P5, and a pad P6. The pad P4, the pad P5, and the pad P6 are disposed on the same layer and separated from each other. The pad P4 may contact and be electrically connected to the metal pad 1381 of the metal layer 138. The pad P5 may contact and be electrically connected to the metal pad 1382 of the metal layer 138, and the pad P5 may also contact and be electrically connected to the copper pillar 120b. The pad P6 may contact and be electrically connected to the copper pillar 120.

In the embodiment, the N-type semiconductor material 133b may be electrically connected to the P-type semiconductor material 134b through the sub-electrode 1352b, the metal pad 1382, the pad P5, the copper pillar 120b, the pad P2, the opening O2, and the sub-electrode 1362b, thereby enabling the N-type semiconductor material 133b and the P-type semiconductor material 134b to be connected in series.

In the embodiment, the first redistribution layer 140 may be electrically connected to the second redistribution layer 150 through the copper pillar 120. The assist layer AL1 is disposed on the side 1401 of the first redistribution layer 140, and the assist layer AL1 may contact the pad P4. The assist layer AL2 is disposed on the side 1501 of the second redistribution layer 150, and the assist layer AL2 may contact the pad P1.

In the embodiment, when current is applied to the first electrode 135b and the second electrode 136b, the first heat transfer element 130b will have heat absorption capability on one side close to the copper pillar 120b, and will have heat dissipation capability on the other side close to the assist layer AL1 and the assist layer AL2, so that the first heat transfer element 130b may generate a heat transfer path to transfer the heat generated by the driving module 160 to the assist layer AL1 and the assist layer AL2, thereby enabling the heat generated by the driving module 160 to be transferred to the outside and increasing the efficiency of heat dissipation.

Then, referring to FIG. 8, a connector 170 is formed, a driving module 160 is formed on the first redistribution layer 140, and a heat sink 200 is configured on the driving module 160.

Then, continuing to refer to FIG. 8, after removing the substrate Sub2 and the release layer RL2, a connector 400 is formed, and the composite circuit stack 100b is configured on the circuit board 300 through the connector 400. Thus far, the electronic device 10b of the embodiment has been substantially completed in manufacture.

In another embodiment, the manufacturing method of the electronic device 10b may also include forming an encapsulation layer on the first redistribution layer 140 and forming an underfill on the circuit board 300. For the formation of the encapsulation layer and the underfill, reference may be made to the description of FIG. 3, and description thereof is thus not repeated herein.

In the embodiment, the heat generated by the driving module 160 may be first transferred to the first redistribution layer 140 through the connector 170. Then, the heat transferred to the first redistribution layer 140 may be further transferred to the assist layer AL1 and the assist layer AL2 through the first heat transfer element 130b, so that the heat generated by the driving module 160 may be transferred to the outside, thereby increasing the efficiency of heat dissipation.

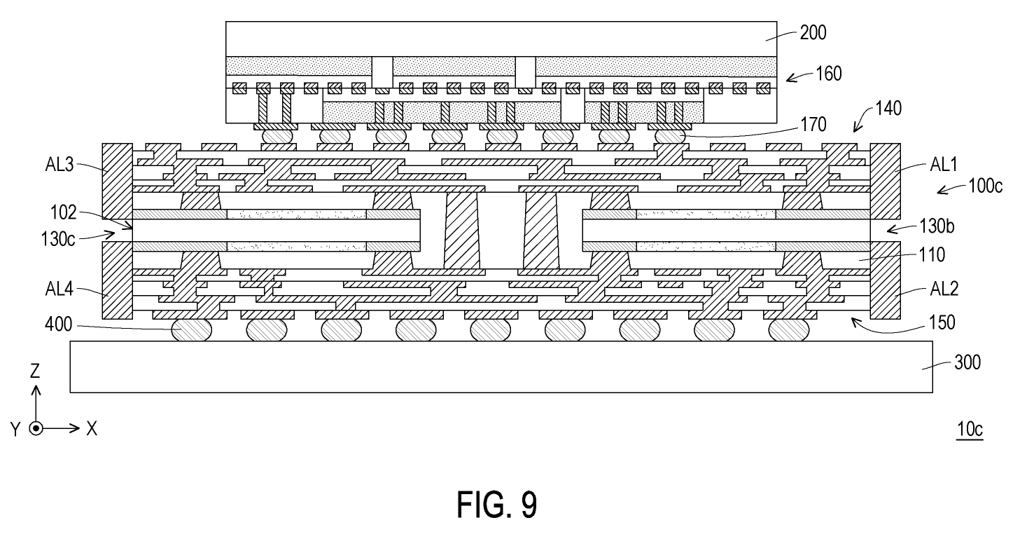

FIG. 9 is a cross-sectional schematic diagram of an electronic device according to the fourth embodiment of the disclosure. Referring to FIG. 9 and FIG. 8 at the same time, an electronic device 10c of the embodiment is similar to the electronic device 10b of FIG. 8, but the difference between the two lies in that, in the electronic device 10c of the embodiment, a composite circuit stack 100c further includes a first heat transfer element 130c, an assist layer AL3, and an assist layer AL4.

Specifically, referring to FIG. 9, the configuration and material of the components in the first heat transfer element 130c may be substantially the same as or similar to the configuration and material of the components in the first heat transfer element 130b, and description thereof is thus not repeated herein.

The first heat transfer element 130c and the first heat transfer element 130b are embedded in two opposite sides of the core substrate 110, respectively. The assist layer AL3 and the assist layer AL4 are also disposed on another side 102 of the composite circuit stack 100c relative to the assist layer AL1 and the assist layer AL2.

In the embodiment, the assist layer AL1 and the assist layer AL2 contact the first heat transfer element 130b, while the assist layer AL3 and the assist layer AL4 contact the first heat transfer element 130c.

In the embodiment, after the heat generated by the driving module 160 is transferred to the first redistribution layer 140, the heat may be further transferred to the assist layer AL1 and the assist layer AL2 through the first heat transfer element 130b, and may also be further transferred to the assist layer AL3 and the assist layer AL4 through the first heat transfer element 130c, so that the heat generated by the driving module 160 may be transferred to the outside, thereby increasing the efficiency of heat dissipation.

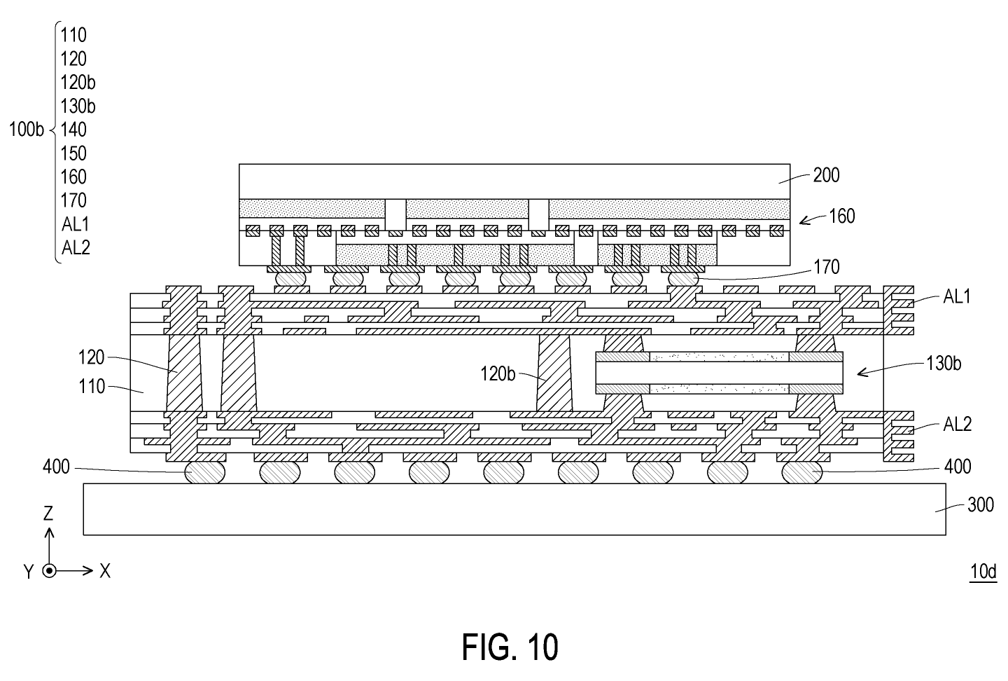

FIG. 10 is a cross-sectional schematic diagram of an electronic device according to the fifth embodiment of the disclosure. Referring to FIG. 10 and FIG. 8 at the same time, an electronic device 10d of the embodiment is similar to the electronic device 10b of FIG. 8, but the difference between the two lies in that, in the electronic device 10d of the embodiment, the assist layer AL1 and the assist layer AL2 further include fin structures to increase the heat dissipation effect.

In summary, in the composite circuit stack of an embodiment of the disclosure, the first heat transfer element and/or the second heat transfer element may transfer the heat generated by the driving module to the second redistribution layer and the circuit board, thereby increasing the efficiency of heat dissipation. In some embodiments, the first heat transfer element may also transfer the heat generated by the driving module to the assist layer, thereby increasing the efficiency of heat dissipation.

Finally, it should be noted that the above embodiments are only used to illustrate the technical solutions of the disclosure, but not to limit them. Although the disclosure has been described in detail with reference to the foregoing embodiments, those of ordinary skill in the art should understand that: The technical solutions described in the foregoing embodiments can still be modified, or some or all of the technical features thereof can be equivalently replaced; and these modifications or replacements do not make the essence of the corresponding technical solutions deviate from the scope of the technical solutions of the embodiments of the disclosure.

What is claimed is:

1. An electronic device, comprising:
a composite circuit stack, comprising:
a core substrate;
at least one first heat transfer element, embedded in the core substrate;
a first redistribution layer, disposed on the core substrate;
a driving module, disposed on the first redistribution layer; and
an encapsulation layer, surrounding the driving module.

2. The electronic device according to claim 1, wherein the at least one first heat transfer element comprises an N-type semiconductor material and a P-type semiconductor material, and the N-type semiconductor material and the P-type semiconductor material are connected in series.

3. The electronic device according to claim 2, wherein the N-type semiconductor material and the P-type semiconductor material of the at least one first heat transfer element are coplanar.

4. The electronic device according to claim 3, wherein the at least one first heat transfer element further comprises:
a metal layer, disposed between the first redistribution layer and the N-type semiconductor material, and electrically connected to the N-type semiconductor material and the P-type semiconductor material.

5. The electronic device according to claim 3, wherein the at least one first heat transfer element further comprises:
a dielectric layer, disposed between the first redistribution layer and the N-type semiconductor material.

6. The electronic device according to claim 5, wherein the dielectric layer contacts the first redistribution layer.

7. The electronic device according to claim 2, wherein the composite circuit stack further comprises a second redistribution layer disposed on the core substrate, and the at least one first heat transfer element further comprises:
a first electrode, disposed on the N-type semiconductor material, and electrically connected to a first pad of the second redistribution layer; and
a second electrode, disposed on the P-type semiconductor material, and electrically connected to a second pad of the second redistribution layer.

8. The electronic device according to claim 7, wherein the first pad and the second pad are disposed on a same layer and separated from each other.

9. The electronic device according to claim 2, wherein the N-type semiconductor material and the P-type semiconductor material of the at least one first heat transfer element are stacked along a normal direction of the composite circuit stack.

10. The electronic device according to claim 9, wherein the composite circuit stack further comprises:
a copper pillar, penetrating through the core substrate, and electrically connected to the N-type semiconductor material and the P-type semiconductor material.

11. The electronic device according to claim 9, wherein the composite circuit stack further comprises:
an assist layer, disposed on a side of the composite circuit stack, and contacting a pad of the first redistribution layer.

12. The electronic device according to claim 11, wherein the pad of the first redistribution layer is electrically connected to the N-type semiconductor material.

13. The electronic device according to claim 9, wherein the composite circuit stack further comprises:
an assist layer, disposed on a side of the composite circuit stack, and contacting the at least one first heat transfer element.

14. The electronic device according to claim 13, wherein the assist layer further comprises a fin structure.

15. The electronic device according to claim 2, wherein the N-type semiconductor material or the P-type semiconductor material comprises bismuth telluride.

16. The electronic device according to claim 1, wherein the composite circuit stack further comprises:
at least one second heat transfer element, embedded in the encapsulation layer, and adjacent to the driving module.

17. The electronic device according to claim 16, further comprising:
a heat sink, disposed on the encapsulation layer, and contacting the at least one second heat transfer element.

18. The electronic device according to claim 17, wherein the heat sink contacts the driving module.

19. The electronic device according to claim 1, wherein the composite circuit stack further comprises:
a second redistribution layer, disposed on the core substrate, and electrically connected to the first redistribution layer.

20. The electronic device according to claim 19, wherein the composite circuit stack further comprises:
another copper pillar, penetrating through the core substrate, and electrically connected to the first redistribution layer and the second redistribution layer.
